(19) United States
(12) Patent Application Publication
(10) Pub. No.: US 2025/0051695 A1
(43) Pub. Date: Feb. 13, 2025

(54) FLUORINATED CLEANING FLUID MIXTURES

(71) Applicant: 3M INNOVATIVE PROPERTIES COMPANY, St. Paul, MN (US)

(72) Inventors: Tamami Kimura, Tokyo (JP); Liping Claryn Ng, Singapore (SG); Nobuaki Ando, Kanagawa (JP)

(21) Appl. No.: 18/719,693

(22) PCT Filed: Dec. 14, 2022
(86) PCT No.: PCT/IB2022/062237

§ 371 Date: Jun. 13, 2024

Related U.S. Application Data
(60) Provisional application No. 63/293,880, filed on Dec. 27, 2021.

(51) Int. Cl. C11D 7/50; H01L 21/02

(52) U.S. Cl. CPC C11D 7/5009; C11D 7/5018; C11D 7/5022; H01L 21/02057

(57) ABSTRACT

Cleaning fluids include at least two fluid components. The first fluid component is a hydrofluorothioether or a chlorinated hydrofluoroolefin, or at least one of the isomers of a hydrochlorofluoroolefin, and the second fluid component is an alcohol with 1-5 carbon atoms. The cleaning fluid provides enhanced removal of particulate contamination, improved reduction of particle reattachment, or a combination thereof when compared to a cleaning fluid comprising a fluorinated fluid.

### SUMMARY

Disclosed herein are fluorinated cleaning fluid mixtures that comprise at least one fluorinated fluid and an alcohol. Also disclosed are methods for cleaning that use the fluorinated cleaning fluid mixtures.

In some embodiments, the cleaning fluid comprises a first fluid component comprising a hydrofluorothioether or a chlorinated hydrofluoroolefin, or at least one of the isomers of a hydrochlorofluoroolefin, and a second fluid component comprising at least one alcohol with 1-5 carbon atoms. The cleaning fluid provides enhanced removal of particulate contamination, improved reduction of particle reattachment, or a combination thereof when compared to a cleaning fluid comprising a fluorinated fluid.

Also disclosed are methods for cleaning articles. In some embodiments, the method comprises providing an article to be cleaned comprising at least one surface with at least one contaminant, providing a cleaning fluid as described above, and contacting the substrate surface with the cleaning fluid.

### DETAILED DESCRIPTION

Cleaning fluids are used in a wide range of applications. Hydrocarbon cleaning fluids such as aromatics (e.g. benzene and toluene) or alkanes (e.g. hexanes and petroleum ether) or mixtures such as gasoline are useful cleaners, but these materials are flammable and therefore hazardous to use as cleaners. Other solvents such as chlorinated solvents have been developed that provide good cleaning performance and are non-flammable, but these materials have drawbacks. Hydrofluoroether fluids are widely used in solvent precision cleaning applications due, at least in part, to their good cleaning performance, zero ozone depletion potential, low global warming potential, and low toxicity. Also, because hydrofluoroether fluids are often nonflammable, they can be used safely in a wide variety of applications.

As articles have become more complex, cleaning and contaminant removal has become more difficult. Cleaning and contaminant removal can be especially challenging for complementary metal-oxide-semiconductor (CMOS) parts with relatively high pixel densities. For such parts, any particles, organic residues, or water stains resulting from wafer dicing, die-attach, and assembly processes can cause a significant adverse impact on the quality of the output image. Thus, an improved cleaning fluid formulation that can provide better cleaning performance and improved particle removal and/or particle reattachment prevention efficiencies are desirable. Therefore, the need remains for cleaning fluids that have desirable cleaning properties, are non-flammable, and are also non-toxic environmentally friendly.

Disclosed herein are cleaning fluids that are mixtures of fluids that provide the desired performance properties of improved particle removal, decreased particle re-attachment, and are non-flammable, and are also environmentally friendly and non-toxic.

In some embodiments, the cleaning fluid comprises at least two fluid components. The first fluid component comprises a hydrofluorothioether, a chlorinated hydrofluoroolefin, or one or more isomers of hydrochlorofluoroolefin. The second fluid component comprises an alcohol comprising 1-5 carbon atoms. Also disclosed are methods of cleaning substrates using the cleaning fluids.

As used herein, “fluoro-” (for example, in reference to a group or moiety, such as in the case of “fluoroalkylene” or “fluoroalkyl” or “fluorocarbon”) or “fluorinated” means (i) partially fluorinated such that there is at least one carbon-bonded hydrogen atom, or (ii) perfluorinated.

As used herein, “perfluoro-” (for example, in reference to a group or moiety, such as in the case of “perfluoroalkylene” or “perfluoroalkyl” or “perfluorocarbon”) or “perfluorinated” means completely fluorinated such that, except as may be otherwise indicated, there are no carbon-bonded hydrogen atoms replaceable with fluorine.

As used herein, the group “—R_{f}” is used according to common usage in chemical arts and refers to fluoralkyl group. The group “—R_{f}—” refers to a fluoroalkylene group.

The terms “room temperature” and “ambient temperature” are used interchangeably to mean temperatures in the range of 20° C. to 25° C.

The term “alkyl” refers to a monovalent group that is a radical of an alkane, which is a saturated hydrocarbon. The alkyl can be linear, branched, cyclic, or combinations thereof.

The term “olefin” is used herein as is well understood in the chemical arts, referring to a molecule with an olefinic group, that is to say a carbon-carbon double bond (—C═C—). which may be terminal or non-terminal. Groups with olefinic groups include chlorinated hydrofluoroolefins which are olefinic groups with a chlorine atom, 2 hydrogen atoms, and a fluorinated group attached; hydrochlorofluoroolefins which are olefinic groups with a chlorine atom, a fluorine atom, a hydrogen atom, and a fluorinated group attached; perfluorinated olefins are olefin groups where all of the hydrogen atoms have been replaced by fluorine atoms; and hydrofluoroolefins are olefin groups that contain at least one hydrogen atom as well as fluorine atoms.

The term “ether” as used herein refers to a compound of the type R^{a}—O—R^{b}, where R^{a} and R^{b} are alkyl, or fluorinated alkyl groups. The term “thioether” refers to an ether compound where the oxygen is replaced by a sulfur atom. The term “hydrofluorothioether” as used herein refers to a thioether of the type R^{a}—S—R^{b}, where R^{a} is an alkyl group and R^{b} is fluorinated alkyl group, typically a perfluoroalkyl group.

Disclosed herein are cleaning fluids that comprise mixtures of fluid components. In some embodiments, the cleaning fluid comprises at least two fluid components. The cleaning fluid comprises a first fluid component comprising a hydrofluorothioether, a chlorinated hydrofluoroolefin, or one or more isomers of hydrochlorofluoroolefin. The second fluid component comprises an alcohol comprising 1-5 carbon atoms. Each of these components is described in greater detail below.

In some embodiments, the first fluid component comprises a hydrofluorothioether of Structure 1:

R¹—S—R_{f}¹ Structure 1

where R¹ is a nonfluorinated alkyl group with 1-3 carbon atoms; R_{f}¹ is a fluorinated or perfluorinated group containing 2-6 carbon atoms and optionally comprises one or more catenated heteroatoms. In some embodiments, R¹ is an alkyl group with 1 carbon atom; and R_{f}¹ is —CR_{f}³R_{f}⁴F group wherein R_{f}³ and R_{f}⁴ are independently perfluorinated alkyl groups with 1-3 carbon atoms. In some, embodiments, R_{f}³ and R_{f}⁴ are perfluorinated alkyl groups with 1 carbon atom.

In other embodiments, the first fluid component comprises a chlorinated hydrofluoroolefin of Structure 2

cis-(CF₃)HC═CHCl; Structure 2.

The cis nomenclature is used herein and is equivalent to the Z nomenclature. The chlorinated hydrofluoroolefin is commercially available as CELEFIN-1233z from Central Glass Co., Ltd. Tokyo, Japan. While the cis isomer is shown in the structure, it is well understood in the chemical arts that some trans isomer might also be present in the fluid.

In other embodiments, the first fluid comprises a hydrochlorofluoroolefin or a mixture of hydrochlorofluoroolefins. The first fluid comprises at least one of the two isomers of hydrochlorofluoroolefin of Structure 3,

HClC═CF(CF₂H) Structure 3

at least one of the two isomers of hydrochlorofluoroolefin of Structure 4,

FClC═CH(CF₂H) Structure 4

or a mixture of two, three or all four of the isomers.

A mixture of the isomers of Structures 3 and 4 is commercially available as AMOLEA AS-300 from (AGC) Asahi Glass Company, Tokyo, Japan.

The first fluid component is the primary component of the cleaning fluid. In some embodiments, the first fluid component comprises 85-99.9% by weight of cleaning fluid.

The cleaning fluid also comprises at least a second fluid component. The second fluid component is an alcohol of structure 5:

R²—OH Structure 5

where R² is an alkyl group with 1-5 carbon atoms.

A wide range of alcohols of Structure 5 are suitable. In some embodiments, the second fluid component comprises an alcohol where R² is an alkyl group with 1-4 carbon atoms. The choice of alcohol can affect the properties of the cleaning fluid. A first class of cleaning fluid composition is a cleaning fluid with improved particle removal when compared to cleaning fluid comprising a fluorinated fluid. A second class of cleaning fluid has an improved reduction of particle re-attachment when compared to cleaning fluid comprising a fluorinated fluid.

In some embodiments of the first class of cleaning fluid, the second fluid component comprises an alcohol where R² is an alkyl group with 2-3 carbon atoms. Examples of suitable alcohols are ethanol, n-propanol, and iso-propanol. In some embodiments, the second fluid component comprises iso-propanol. The cleaning fluid may also comprise a third fluid component, or another additive. In some embodiments, the third fluid component comprises an alcohol or a hydrofluoro ether. Examples of hydrofluoro ethers include, for example, 3M NOVEC 7100 Engineered Fluid and AGC ASAHIKLIN AE-3000. As mentioned above, the first class of cleaning fluid demonstrates improved particle removal when compared to cleaning fluid comprising a fluorinated fluid.

In some embodiments of the second class of cleaning fluid, the second fluid component comprises an alcohol where R² is an alkyl group with 4 carbon atoms. Examples of suitable alcohols are the isomers of butanol: n-butanol (1-butanol); sec-butanol; iso-butanol (2-methyl-1-propanol); and tert-butanol. The cleaning fluid may also comprise a third fluid component, or another additive. In some embodiments, the third fluid component comprises an alcohol or a hydrofluoro ether. Examples of hydrofluoro ethers include, for example, 3M NOVEC 7100 Engineered Fluid and AGC ASAHIKLIN AE-3000. As mentioned above, the second class of cleaning fluid demonstrates improved reduction of particle re-attachment when compared to cleaning fluid comprising a fluorinated fluid.

As mentioned above, the cleaning fluids of this disclosure have a wide range of desirable properties. The cleaning fluids are non-flammable. Suitable tests for flammability are well understood in the cleaning fluid art.

The cleaning fluids of this disclosure are also environmentally friendly. By this it is meant that the cleaning fluids may have a low environmental impact. In this regard, the fluorinated compounds of the present disclosure may have a global warming potential (GWP, 100 yr ITH) of less than 500, 300, 200, 100, 50, 10, or less than 1. As used herein, GWP is a relative measure of the global warming potential of a compound based on the structure of the compound. The GWP of a compound, as defined by the Intergovernmental Panel on Climate Change (IPCC) in 1990 and updated in 2007, is calculated as the warming due to the release of 1 kilogram of a compound relative to the warming due to the release of 1 kilogram of CO₂ over a specified integration time horizon (ITH).

$${GWP}_{i} ( {t}^{′} ) = \frac{{\int }_{0}^{ITH} {a}_{i} [ C ( t ) ] dt}{{\int }_{0}^{ITH} {a}_{{CO}_{2}} [ {C}_{{CO}_{2}} ( t ) ] dt} = \frac{{\int }_{0}^{ITH} {a}_{i} {C}_{oi} {e}^{- t / τ} dt}{{\int }_{0}^{ITH} {a}_{{CO}_{2}} [ {C}_{{CO}_{2}} ( t ) ] dt}$$

In this equation aᵢ is the radiative forcing per unit mass increase of a compound in the atmosphere (the change in the flux of radiation through the atmosphere due to the IR absorbance of that compound), C is the atmospheric concentration of a compound, τ is the atmospheric lifetime of a compound, t is time, and i is the compound of interest. The commonly accepted ITH is 100 years representing a compromise between short-term effects (20 years) and longer-term effects (500 years or longer). The concentration of an organic compound, i, in the atmosphere is assumed to follow pseudo first order kinetics (i.e., exponential decay). The concentration of CO₂ over that same time interval incorporates a more complex model for the exchange and removal of CO₂ from the atmosphere (the Bern carbon cycle model).

Also disclosed herein are methods for cleaning articles. In some embodiments, the method for cleaning an article comprises providing an article to be cleaned comprising at least one surface that comprises at least one contaminant, providing a cleaning fluid as described above, and contacting the substrate surface with the cleaning fluid. The cleaning fluid can be used in either the gaseous or the liquid state (or both), and any of the known techniques for “contacting” a substrate can be utilized. For example, a liquid cleaning composition can be sprayed, brushed, or spin coated onto the substrate, a gaseous cleaning composition can be blown across the substrate, or the substrate can be immersed in either a gaseous or a liquid composition. Elevated temperatures, ultrasonic energy, and/or agitation can be used to facilitate the cleaning. In some embodiments, the method further comprises removing the cleaning fluid from the substrate surface by evaporating the cleaning fluid or removing the substrate from immersion in the cleaning fluid.

Various solvent cleaning techniques are described by Barbara and Edward Kanesburg, Handbook of Critical Cleaning: Cleaning Agents and Systems, edited by CRC Press, pages 123-127 and 363-372 (2011); and B. N. Ellis in Cleaning and Contamination of Electronics Components and Assemblies, Electrochemical Publications Limited, Ayr, Scotland, pages 182-94 (1986).

Both organic and inorganic substrates can be cleaned by the cleaning methods of the present disclosure. Representative examples of the substrates include metals; ceramics; glass; semiconductors; polycarbonate; polystyrene; acrylonitrile-butadiene-styrene copolymer; synthetic non-woven materials; natural fibers (and fabrics derived therefrom) such as cotton, silk, fur, suede, leather, linen, and wool; synthetic fibers (and fabrics) such as polyester, rayon, acrylics, nylon, and blends thereof; fabrics comprising a blend of natural and synthetic fibers; and composites of the foregoing materials. The process may be useful in the precision cleaning of optical and electronic components, subassemblies, or devices, such as circuit boards, wafers and integrated circuit chips (including those based on Si, Ge and Si/Ge semiconductors), CMOS parts, display components, optical or magnetic media, UV or EUV photomasks (such as those used in semiconductor photolithography), as well as various medical devices.

In some embodiments, the cleaning processes of the present disclosure can be used to dissolve or remove most contaminants from the surface of a substrate. For example, materials such as light hydrocarbon contaminants; higher molecular weight hydrocarbon contaminants such as mineral oils and greases; fluorocarbon contaminants such as perfluoropolyethers, bromotrifluoroethylene oligomers (gyroscope fluids), and chlorotrifluoroethylene oligomers (hydraulic fluids, lubricants); silicone oils and greases; solder fluxes: particulates; and other contaminants encountered in precision, electronic, metal, and medical device cleaning can be removed. In some embodiments, the process may be used for the removal of hydrocarbon contaminants (especially, light hydrocarbon oils), fluorocarbon contaminants, and organic and inorganic particulates.

As was mentioned above, the current cleaning fluids demonstrate a variety of desirable properties such as improved particle removal when compared to cleaning fluid comprising a fluorinated fluid, improved reduction of particle re-attachment when compared to cleaning fluid comprising a fluorinated fluid, or a combination of properties.

The methods for cleaning articles can be carried out in a variety of ways. In some embodiments, the cleaning is carried out by hand, in other embodiments the cleaning is carried out using automated processes. A wide range of cleaning machines can be used in the cleaning process as is well understood in the art.

### EXAMPLES

These examples are merely for illustrative purposes only and are not meant to be limiting on the scope of the appended claims. All parts, percentages, ratios, etc. in the examples and the rest of the specification are by weight, unless noted otherwise.

Table of Abbreviations

| Abbreviation | Description |
|---|---|
| HFTE | A hydrofluorothioether, CH₃—S—C(CF₃)₂F, available from 3M |
| | Company, St. Paul, Minnesota. |
| 71IPA | HFE-Alcohol blend, “NOVEC 71IPA”, from 3M Company. |
| AS-300 | A mixture of isomers of two hydrochlorofluoroolefins, |
| | HClC═CF(CF₂H) and FClC═CH(CF₂H), available under the trade |
| | designation “AMOLEA AS-300”, from (AGC) Asahi Glass Company, |
| | Tokyo, Japan. |
| 7100 | A hydrofluoroether, methoxy-nonafluorbutane, available under the |
| | trade designation “3M NOVEC 7100 Engineered Fluid”, from 3M |
| | Company. |
| IPA | Isopropanol |
| EtOH | Ethanol |
| BuOH | 1-Butanol |
| 1-PrOH | 1-propanol |

### Test Methods

### Cleaning Performance: Particle Removal

A study was conducted using solvent mixtures to determine the cleaning performance of the fluids. The cleaning trials were performed on heavily soiled CMOS (complementary metal-oxide-semiconductor) sensors containing a high pixel density. These sensors are known to be extremely difficult to clean such that they are essentially free of particle contaminants.

A precision solvent cleaning system (SK-04Y-6008 customized cleaning system from YMPT, Thailand) was used to clean the CMOS sensors using the process outlined in Process 1 below.

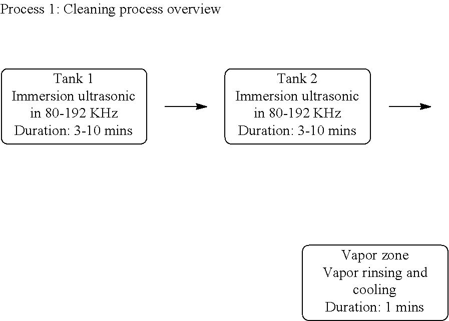

The cleaning performance of each cleaning fluid composition was judged based on the percentage of particles originally present on the CMOS surface that were removed by the cleaning fluid after completion of the cleaning process. The percentage of particles removed was determined by optical microscopy inspection of the CMOS sensors before and after cleaning.

The original (heavily soiled) CMOS sensor was first inspected using an optical microscope and a series of Pre-Clean images were recorded. The CMOS sensor was then cleaned in the precision cleaning system using the process described above and the proscribed solvent/surfactant combination. After cleaning, the CMOS sensor was inspected again by optical microscopy and a Post-Clean image recorded to determine particle counts remaining on the sensor. In this way, the % removal of particles after cleaning of CMOS sensors was determined. The average of 2 samples are reported. The Cleaning Performance is characterized by the following criteria:

Cleaning Performance

| Rating | Description |
|---|---|
| Excellent | >80% Particle Removal |
| Average | 50-80% Particle Removal |
| Below Average | 30-50% Particle Removal |
| Poor | <30% Particle Removal |

### Cleaning Performance: Particle Reattachment

According to theory, particle cleaning performance depends on two processes: (1) particle removal, (2) particle re-attachment. Process (2) is believed to be critical to overall cleaning performance. Therefore, the following experiment was designed to measure the particle reattachment performance of fluids.

Test solutions were prepared. Then, Silicon-nitride particles (Si₃N₄, with an average particle diameter is 1.5 micrometers) were mixed (concentration: 0.01 grams of particles/liter of fluid) into each test solution and stirred with ultrasonic waves for 1 hour. A pre-cleaned bare silicon wafer (4 inch (10 centimeter) diameter) was then dipped into each test solution mixture allowing 3 seconds to immerse each wafer, followed by a 4 second hold at full immersion, 3 seconds to remove each wafer, and allowed to dry. The total particle count (number of attached particles on each wafer) was measured with a microscope (VH-ZST from Keyence). The results are reported according to the following criteria:

Particle Attachment Performance

| Rating | General Description | Description |
|---|---|---|
| 5 | Excellent | <70 Particles Reattached per mm² |
| 4 | Very good | 70-90 Particles Reattached per mm² |
| 3 | Average | 90-110 Particles Reattached per mm² |
| 2 | Below Average | 110-130 Particles Reattached per |
| | | mm² |
| 1 | Poor | >130 Particles Reattached per mm² |

### EXAMPLES

### Examples E1-E5 and Comparative Examples CE1-CE2: Particle Removal Testing

A series of fluids and fluid mixtures were tested using the Particle Removal Test Method described above. The Results are shown in Table 1 below.

TABLE 1
Particle Removal

| Example | Fluid Description | Efficiency Rating |
|---|---|---|
| CE1 | 100% 71IPA | Excellent |
| CE2 | 100% HFTE | Excellent |
| E1 | HFTE + 5% IPA | Excellent |
| E2 | HFTE + 5% EtOH | Poor |
| E3 | 2 cycles HFTE + 5% EtOH | Average |
| E4 | HFTE + 5% EtOH and HFTE + 5% IPA | Excellent |
| E5 | 2 cycles HFTE + 5% EtOH and HTFE + BuOH | Below Average |

### Examples E6-E8: Particle Reattachment Testing

A series of fluids and fluid mixtures were tested using the Particle Reattachment Test Method described above. Example E6 are fluids based upon HFTE, and the results are shown in Table 2 below. Example E7 are fluids based upon AS-300, and the results are shown in Table 3 below. Example E8 are fluids based upon 7100, and the results are shown in Table 4 below.

TABLE 2
HFTE Fluids

| Wt % of | | | | | |
|---|---|---|---|---|---|
| additive | MeOH | EtOH | 1-PrOH | BuOH | IPA |
| 0 | 1 | 1 | 1 | 1 | 1 |
| 2 | 4 | | | | 2 |
| 4 | | 3 | | 3 | 4 |
| 5 | 5 | 3 | 4 | 4 | 4 |
| 6 | 5 | | 4 | | 4 |
| 8 | | | | | 4 |
| 10 | 5 | 4 | 4 | 5 | 5 |

TABLE 3
AS-300 Fluids

| Wt % of | | | | | |
|---|---|---|---|---|---|
| additive | MeOH | EtOH | 1-PrOH | BuOH | IPA |
| 0 | 1 | 1 | 1 | 1 | 1 |
| 2 | 4 | | | 3 | |
| 4 | | | 3 | | |
| 5 | 5 | 3 | 4 | 4 | 1 |
| 6 | | | 5 | 5 | 3 |
| 8 | | 4 | | | 4 |
| 10 | 5 | | | | |

TABLE 4
7100 Fluids

| Wt % of | | | | | |
|---|---|---|---|---|---|
| additive | MeOH | EtOH | 1-PrOH | BuOH | IPA |
| 0 | 1 | 1 | 1 | 1 | 1 |
| 2 | | 3 | 3 | | 2 |
| 4 | 4 | | | | 2 |
| 5 | 3 | 4 | 4 | 4 | 3 |
| 6 | | 4 | | | 4 |
| 8 | 5 | | 5 | 5 | 4 |
| 10 | | | | | 4 |

What is claimed is:

1. A cleaning fluid comprising:
a first fluid component comprising a hydrofluorothioether of Structure 1:
R¹—S—R_{f}¹ Structure 1
wherein R¹ is a nonfluorinated alkyl group with 1-3 carbon atoms;
R_{f}¹ is a fluorinated or perfluorinated group containing 2-6 carbon atoms and optionally comprises one or more catenated heteroatoms; or a chlorinated hydrofluoroolefin of Structure 2
cis-(CF₃)HC═CHCl; Structure 2; or
at least one of the two isomers of hydrochlorofluoroolefin of Structure 3,
HClC=CF(CF₂H) Structure 3
at least one of the two isomers of hydrochlorofluoroolefin of Structure 4,
FClC═CH(CF₂H) Structure 4
or a mixture thereof, and
a second fluid component comprising at least one alcohol comprising structure 5:
R²—OH Structure 5
wherein R² is an alkyl group with 1-5 carbon atoms,
wherein the cleaning fluid provides enhanced removal of particulate contamination, improved reduction of particle reattachment, or a combination thereof when compared to a cleaning fluid comprising a fluorinated fluid.

2. The cleaning fluid of claim 1, wherein the first fluid component comprises a hydrofluorothioether of Structure 1:
wherein R¹ is an alkyl group with 1 carbon atom; and
R_{f}¹ is a —CR_{f}³R_{f}⁴F group wherein R_{f}³ and R_{f}⁴ are independently perfluorinated alkyl groups with 1-3 carbon atoms.

3. The cleaning fluid of claim 2, wherein R_{f}³ and R_{f}⁴ are perfluorinated alkyl groups with 1 carbon atom.

4. The cleaning fluid of claim 1, wherein the first fluid component comprises 85-99.9% by weight of cleaning fluid.

5. The cleaning fluid of claim 1, wherein the second fluid component comprises an alcohol where R² is an alkyl group with 1-4 carbon atoms.

6. The cleaning fluid of claim 5, wherein the second fluid component comprises an alcohol where R² is an alkyl group with 2-3 carbon atoms.

7. The cleaning fluid of claim 6, wherein the second fluid component comprises iso-propanol, and wherein the cleaning fluid provides improved particle removal when compared to cleaning fluid comprising a fluorinated fluid.

8. The cleaning fluid of claim 7, further comprising at least a third fluid component, wherein the third fluid component comprises an alcohol.

9. The cleaning fluid of claim 1, wherein the second fluid component comprises an alcohol where R² is an alkyl group with 4 carbon atoms.

10. The cleaning fluid of claim 1, wherein the second fluid component comprises butanol, and wherein the cleaning fluid provides an improved reduction of particle re-attachment when compared to cleaning fluid comprising a fluorinated fluid.

11. The cleaning fluid of claim 10, further comprising at least a third fluid component, wherein the third fluid component comprises an alcohol.

12. The cleaning fluid of claim 1, wherein the cleaning fluid is non-flammable.

13. A method of cleaning an article comprising:
providing an article to be cleaned comprising at least one surface that comprises at least one contaminant;
providing a cleaning fluid comprising:
a first fluid component comprising a hydrofluorothioether of Structure 1:
R¹—S—R_{f}¹ Structure 1
wherein R¹ is a nonfluorinated alkyl group with 1-3 carbon atoms;
R_{f}¹ is a fluorinated or perfluorinated group containing 2-6 carbon atoms and optionally comprises one or more catenated heteroatoms; or a chlorinated hydrofluoroolefin of Structure 2
cis-(CF₃)HC═CHCl; Structure 2; or
at least one of the two isomers of hydrochlorofluoroolefin of Structure 3,
HClC=CF(CF₂H) Structure 3
at least one of the two isomers of hydrochlorofluoroolefin of Structure 4,
FClC═CH(CF₂H) Structure 4
or a mixture thereof, and
a second fluid component comprising at least one alcohol comprising structure 5:
R²—OH Structure 5
wherein R² is an alkyl group with 1-5 carbon atoms; and
contacting the substrate surface with the cleaning fluid.

14. The method of claim 13, wherein contacting the substrate surface with the cleaning fluid comprises applying the cleaning fluid by brushing, spraying, or spin coating.

15. The method of claim 13, wherein contacting the substrate surface with the cleaning fluid comprises immersion of the substrate in the cleaning fluid.

16. The method of claim 13, further comprising removing the cleaning fluid from the substrate surface.

17. The method of claim 16, wherein removing the cleaning fluid from the substrate surface comprises evaporating the cleaning fluid or removing the substrate from immersion in the cleaning fluid.
